(19) United States
(12) Patent Application Publication
(10) Pub. No.: US 2006/0273804 A1
(43) Pub. Date: Dec. 7, 2006

(54) Capacitive measuring sensor and associated ,measurement method

(75) Inventors: Nicolas Delorme, Grenoble (FR); Cyril Condemine, Grenoble (FR); Marc Belleville, St. Egreve (FR)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: COMMISSARIAT A L'ENERGIE ATOMIQUE, Paris (FR)

(21) Appl. No.: 10/559,379

(22) PCT Filed: Jun. 17, 2004
(86) PCT No.: PCT/FR04/50277

§ 371 Date: Dec. 6, 2005

(30) Foreign Application Priority Data
Jun. 20, 2003 (FR) 03/50236

(51) Int. Cl. G01R 27/26

(52) U.S. Cl. 324/658; 324/661

(57) ABSTRACT

The invention relates to a capacitive measuring sensor including at least one measuring capacitor (Cm) and means (I1, I2, I3) for applying, in a measuring phase, an actuation voltage to at least one plate of the measuring capacitor.

### TECHNICAL FIELD OF THE INVENTION

This invention relates to a capacitive measuring sensor and a capacitive sensor measuring method.

The invention applies to microsystems including a capacitive sensor and an electronic unit for measurement and actuation of the sensor, such as, for example, capacitive accelerometers.

According to the prior art, a capacitive sensor includes at least one capacitor having at least one mobile plate. The movement of the mobile plate(s) of the capacitive sensor causes a variation in the measured capacitance.

The measuring sensitivity of a capacitive sensor is dependent on the relative position of the plates at the beginning of the measurement. However, with respect to an optimal starting position (rest position), the plates of a sensor subjected to a plurality of deformations can be found, at the end of a given time period, significantly offset with respect to one another. It is thus necessary to expose the plates to an actuation voltage in order to urge them to return to their rest position.

The amplitudes of the voltages applied to the capacitive sensors are generally low for carrying out measurements (for example, 1v) and higher for repositioning the plates (for example, 4V).

There are different ways in which to perform the measurement and actuation of a capacitive sensor in a given time interval.

A first way consists of splitting the time interval into a measurement period and an actuation period. The actuation period is then generally longer than the measurement period, which imposes a speed constraint, and, therefore, a consumption constraint on the read-out circuit.

A second way consists of carrying out a spatial separation of the sensor so as to have electrodes dedicated to the measurement and electrodes dedicated to the actuation. For a given sensor size, it amounts to reducing the size of the sensitive element with respect to a drive portion and, consequently, to reducing the signal dynamic. This results in a degradation in the measurement performance in terms of noise. This degradation must then be compensated by a noise-optimised electronic measurement unit.

A third way consists of performing a frequency separation of the measurement and actuation functions. Typically, the measurements are performed by sinusoidal excitation and synchronous demodulation and the actuation is performed by a DC voltage. The circuit is thus particularly complex and leads to an increase in consumption.

The invention does not have the disadvantages mentioned above.

### DESCRIPTION OF THE INVENTION

Indeed, the invention relates to a capacitive sensor including at least one measuring capacitor having a first plate and a second plate, of which at least one plate is a mobile plate capable of moving with respect to a rest position when, in a measuring phase, a measuring voltage is applied between the first and second plates, characterised in that it includes means for applying, simultaneously to the measuring voltage, between the first and second plates, an actuation voltage capable of bringing the first an second plates to a position substantially equal to the rest position.

According to an additional feature of the invention, the means for applying, in a measuring phase, an actuation voltage to a plate of the measuring capacitor include:

a first switch having a first terminal connected to the first plate of the measuring capacitor and a second terminal connected to a first voltage Vh, which first switch is controlled by a first clock signal, and

a second switch having a first terminal connected to the second plate of the measuring capacitor and a second terminal connected to a first operation voltage Vp1 so that:
Vp1=Vdd+Va

where Va is the actuation voltage and Vdd is a second voltage, which second switch is controlled by a second additional clock signal and not overlapping the first clock signal, and

a third switch having a first terminal connected to the second plate of the measuring capacitor and a second terminal connected to a second operation voltage Vp2 so that:
Vp2=Vref+Va,

where Vref is a reference voltage,

which third switch is controlled by the first clock signal.

According to a first embodiment of the invention, the second plate of the measuring capacitor is connected to the first terminal of a fourth switch of which the second terminal is connected to the inverting input of an operational amplifier of which the supply voltage is the second voltage Vdd and of which the non-inverting input is connected to the reference voltage Vref, wherein the fourth switch is controlled by the second clock signal, a fifth switch and a negative feedback capacitance are mounted parallel between the inverting input and the output of the operational amplifier, and the fifth switch is controlled by the first clock signal.

According to another embodiment of the invention, the second plate of the measuring capacitor is connected to a first plate of an insulation capacitor of which the second plate is connected to the inverting input of an operational amplifier, wherein a fourth switch controlled by the second clock signal has a first terminal connected to the first plate of the insulation capacitor, a fifth switch controlled by the first clock signal has a first terminal connected to the second plate of the insulation capacitor, the fourth and fifth switches have their second terminals connected to one another and to a first plate of a negative feedback capacitor, of which the second terminal is connected to the output of the operational amplifier, wherein a sixth switch controlled by the first clock signal is mounted parallel with respect to the negative feedback capacitor, the operational amplifier has a non-inverting input connected to the reference voltage Vref of lower amplitude than the amplitude of the first voltage Vh, and the second voltage Vdd is the supply voltage of the operational amplifier.

According to yet another embodiment of the invention, the second plate of the measuring capacitor is connected to a first plate of an insulation capacitor of which the second plate is connected to the inverting input of an operational amplifier, wherein a fourth switch controlled by the second clock signal has a first terminal connected to the first plate of the insulation capacitor, a fifth switch controlled by the first clock signal has a terminal connected to the second plate of the insulation capacitor, the fourth and fifth switches have their second terminals connected to one another, a negative feedback capacitor has a first plate connected to the second terminals of the fourth and fifth switches by means of a sixth switch controlled by the second clock signal, and to the first voltage Vh by means of a seventh switch controlled by the first clock signal, and a second plate connected to the reference voltage Vref by means of an eighth switch controlled by the first clock signal, and to the output of an operational amplifier by means of a ninth switch controlled by the second clock signal, wherein a tenth switch controlled by the first clock signal has a first terminal connected to the second terminals of the fourth and fifth switches and a second terminal connected to the output of the operational amplifier of which the non-inverting input is connected to the reference voltage Vref, and the second voltage Vdd is the supply voltage of the operational amplifier.

The invention also relates to a measuring method with the help of a capacitive sensor including at least one measuring capacitor having a first and a second plate of which at least one plate is a mobile plate capable of moving, with respect to a rest position, when a measuring voltage is applied between the first and second plates, characterised in that it includes, simultaneously to the application of a measuring voltage between the first and second plates, the application, between said first and second plates, of an actuation voltage capable of bringing the first and second plates to a position substantially equal to the rest position.

The invention is based on the principle of switched capacitors and enables the disadvantages of the techniques of the prior art described above to be avoided. Its general principle is to adjust the voltages for charging and discharging a measuring capacitor in the direction required by the actuation, so as to simultaneously perform the actuation and the measurement.

### BRIEF DESCRIPTION OF THE FIGURES

Other features and advantages of the invention will appear in the description of a preferred embodiment with reference to the appended figures in which:

FIG. 1 shows a capacitive measuring sensor according to the invention;

FIG. 2A shows clock voltages applied to a capacitive measuring sensor according to the invention;

FIG. 2B shows potentials applied, for the measurement and/or for the actuation, to a capacitor plate for measurement of the capacitive sensor according to the invention;

FIG. 2C shows the change in voltage at the terminals of a measuring capacitor of a capacitive sensor according to the invention;

FIG. 2D shows the voltage at the output of a capacitive measuring sensor according to the invention;

FIG. 3 shows a first improvement of the capacitive measuring sensor according to the invention;

FIG. 4 shows a second improvement of the capacitive measuring sensor according to the invention.

In all of the figures, the same references are used to designate the same elements.

### DETAILED DESCRIPTION OF EMBODIMENTS OF THE INVENTION

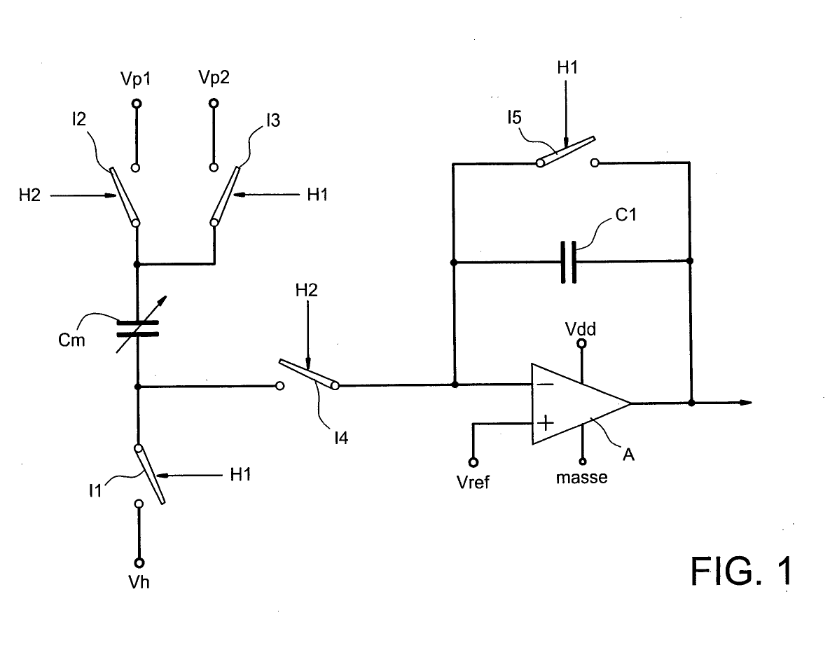

FIG. 1 shows a capacitive sensor according to the invention.

The capacitive sensor includes a measuring capacitor Cm having at least one mobile plate, five switches I1, I2, I3, I4, I5, a negative feedback capacitor C1 and an operational amplifier A.

The switch I1 has a first terminal connected to a first plate of the capacitor Cm and a second terminal connected to a first voltage Vh which is equal, for example, to Vdd/2, where Vdd is the supply voltage of the circuit. The switch I1 is controlled by a clock signal H1.

The switches I2 and I3 have a first common terminal connected to a second plate of the measuring capacitor Cm, the switch I2 having its second terminal connected to a voltage Vp1 and the switch I3 having its second terminal connected to a voltage Vp2. The switches I2 and I3 are controlled by respective clock signals H2 and H1.

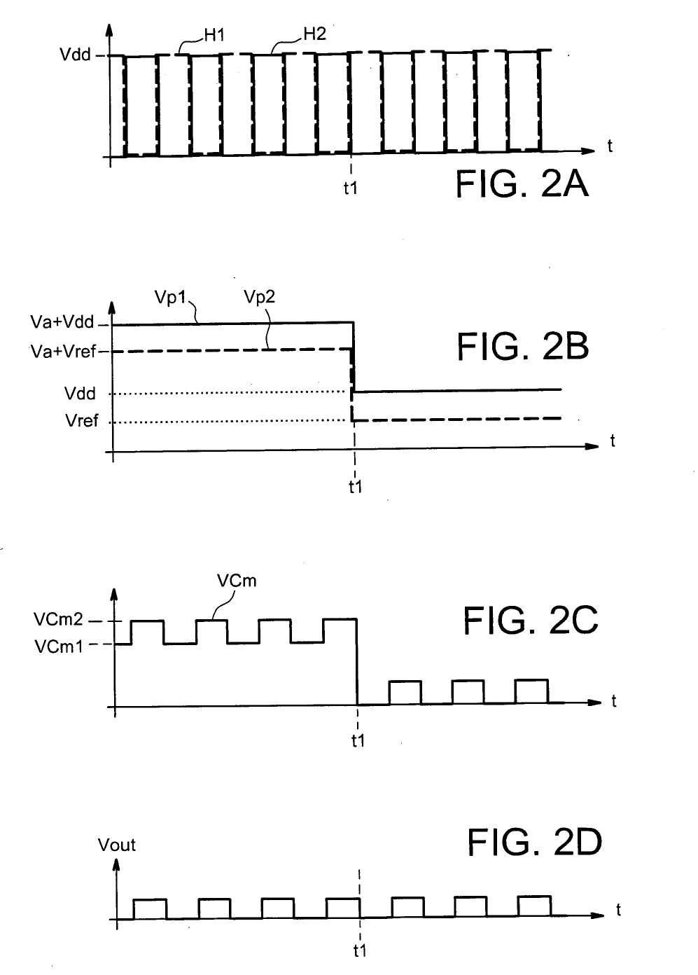

The clock signals H1 and H2 are complementary non-overlapping voltage windows having for high level, for example, the supply voltage Vdd and for low level, for example, the ground which can be equal to 0V. When the clock signal H1 is high, the clock signal H2 is low, and conversely (cf. FIG. 2A).

The switch I4 has a first terminal connected to the first plate of the measurement plate Cm and a second terminal connected to the inverting input of the operational amplifier A of which the non-inverting input is connected to the reference voltage Vref. The switch I4 is controlled by the clock signal H2. The operational amplifier A is supplied by the voltage Vdd.

The switch I5 has a first terminal connected to the inverting input of the operational amplifier A of which the output is connected to the second terminal of the switch I5. The capacitor C1 has a first plate connected to the inverting input of the operational amplifier and a second plate connected to the output of the operational amplifier. The switch I5 is controlled by the clock signal H1.

When the clock signal H1 is high (and therefore the clock signal H2 is low), the switches I1, I3 and I5 are closed and the switches I2 and I4 are open. The difference in potential at the terminals of the capacitor Cm is thus written:
VCm1=Vp2−Vh

The inverting input of the amplifier A is insulated from the capacitor Cm (switch I4 open). The operational amplifier A is then in follower mode (switch I5 closed). The output of the operational amplifier A is stabilized approximately at the Vref voltage.

When the clock signal H2 is high (and therefore the clock signal H1 is low), the switches I1, I3 and I5 are open and the switches I2 and I4 are closed. The first plate of the measuring capacitor Cm is virtually brought to the reference voltage Vref (switch I4 closed) and the second plate is brought to the potential Vp1 so that the difference in potential that appears at the terminals of the capacitor Cm is written:
VCm2=Vp1−Vref

From one clock level to the other, the balance of charges ΔQ delivered by the capacitor Cm is thus written:
ΔQ=Cm(VCm2−VCm1), that is
ΔQ=Cm(Vp1−Vp2)+Cm(Vh−Vref)

In general, Vh=Vref where
ΔQ=Cm(Vp1−Vp2)

The voltage change ΔVout at the output of the operational amplifier is written:
ΔVout=ΔQ/C1

With Va being the value of the desired actuation voltage, by setting the voltages Vp2 and Vp1 as follows:
Vp2=Vref+Va, and
Vp1=Vdd+Va,

it becomes:
ΔVout=Cm(Vdd−Vref)/C1

Advantageously, the voltage measured at the output of the capacitive sensor varies linearly as a function of the capacitance of the measuring capacitor and is not dependent on the actuation voltage Va.

Measurements can thus be carried out when an actuation voltage is applied.

As mentioned above, when the clock signal H1 is high, the voltage at the terminals of the capacitor Cm is written:
VCm1=Vp2−Vh

Similarly, when the clock signal H2 is high, the voltage at the terminals of the capacitor Cm is written:
VCm2=Vp1−Vref
However:
Vp2=Vref+Va, and
Vp1=Vdd+Va

It follows that, if Vh=Vref:
VCm1=Va, and
VCm2=Va+Vdd−Vref

The voltage applied to the terminals of the capacitor Cm therefore does not have a constant value. It has been noted that this has no adverse effects on the operation of the capacitive sensor.

An example of the operation of the capacitive sensor according to the invention is given in FIGS. 2A to 2D:

FIG. 2A shows the clock voltages H1 and H2;

FIG. 2B shows a change in potentials Vp1 and Vp2;

FIG. 2C shows the change in the voltage VCm at the terminals of the measuring capacitor;

FIG. 2D shows the voltage at the output of the capacitive sensor.

As a non-limiting example, the values of the voltages Vdd and Va can be:
Vdd=3, 3V, and
Va=4V

The clock signals H1 and H2 are thus complementary voltage windows that change between 3, 3V (vdd) and zero volt (cf. FIG. 2A). The voltages Vh and Vref are equal to 1,65V (Vdd/2). The actuation voltage equal to 4V is applied from t=0 to t=t1. The voltages Vp2 and Vp1 are then equal to 5,65V and 7,3V, respectively. Beyond t=t1, no actuation voltage is applied.

In some applications, the voltage Vh which is applied at the clock signal H1 rate to the first plate of the capacitor Cm and, consequently, to the inverting input of the operational amplifier A, can reach values high enough to damage the operational amplifier A. This is the case, for example, when the sensor, by virtue of its design, requires a high polarisation at its electrode, or when the configuration of the circuit in which the sensor is included causes this electrode to be exposed to a high voltage. It is then necessary to protect the inverting input of the operational amplifier.

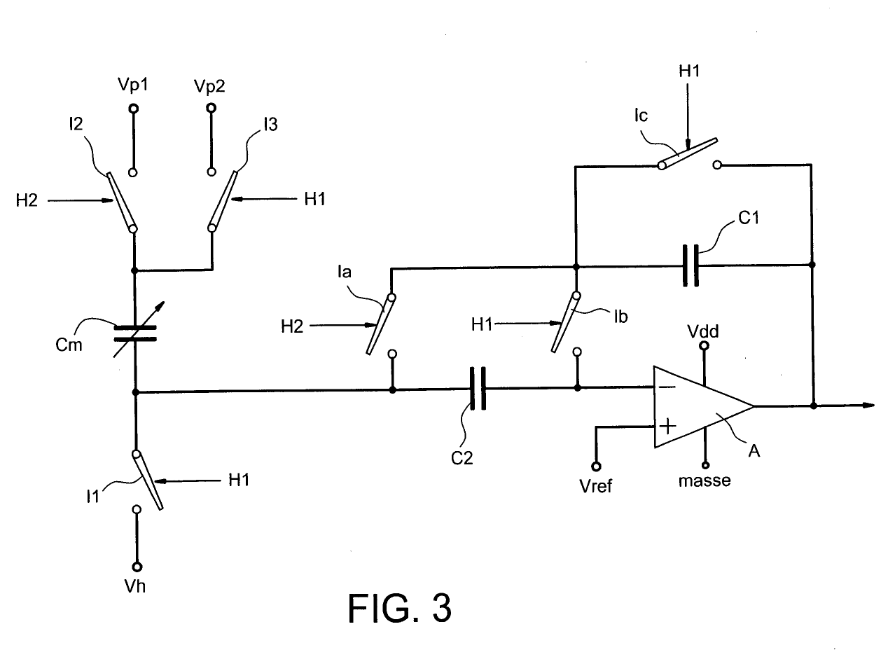

FIG. 3 shows a first circuit according to the invention enabling the inverting input of the operational amplifier to be protected from the application of an excessively high reference voltage.

The first plate of the capacitor Cm is in this case connected to the inverting input of the operational amplifier A by means of an insulation capacitor C2. A fourth switch Ia has a first terminal connected to the first plate of the capacitor Cm and to a first terminal of the capacitor C2. A fifth switch Ib has a first terminal connected to the second plate of the capacitor C2 and to the second terminal of the switch Ia. The common terminal of the switches Ia and Ib is connected to the first plate of the capacitor C1 and to the first terminal of a switch Ic of which the second terminal is connected to the output of the operational amplifier A. The clock signal H2 controls the switch Ia and the clock signal H1 controls the switch Ib. A reference voltage Vref, of lower amplitude than that of the high voltage Vh which is applied to the second terminal of the switch I1, is applied to the non-inverting input (+) of the operational amplifier A. The voltage Vdd is also applied as a supply voltage of the operational amplifier A.

When the clock signal H1 controls the closure of the switch I1, the switch Ib is also closed and the switch Ia is open. The inverting input of the amplifier A, insulated from the high voltage Vh, is brought to the potential Vref.

When the clock signal H1 controls the opening of the switch I1, the switch Ib is also open and the switch Ia is closed. The first plate of the capacitor Cm is then connected to the first plate of the capacitor C1 of which the potential is equal to the high voltage Vh. The switch Ib, which is open, protects the inverting input from the application of the potential Vh.

In every case, the inverting input of the operational amplifier A is thus protected from the high voltage Vh. The circuit according to the improvement of FIG. 3 also has the advantage of being freed from the offset voltage of the operational amplifier A and of multiplying the actual gain of the latter.

The circuit shown in FIG. 3, however, has the disadvantage of transferring the high voltage Vh to the voltage swing at the output of the operational amplifier. Indeed, when the clock H1 is active, the capacitor C1 is discharged. The voltage at its terminals is therefore zero. When the clock H2 is active, by means of the capacitor C2, the voltage Vh is imposed on one of its electrodes. As the capacitor C1 is initially discharged, the voltage Vh is also found at its second electrode, increased by a voltage corresponding to the charge coming from the capacitor Cm.

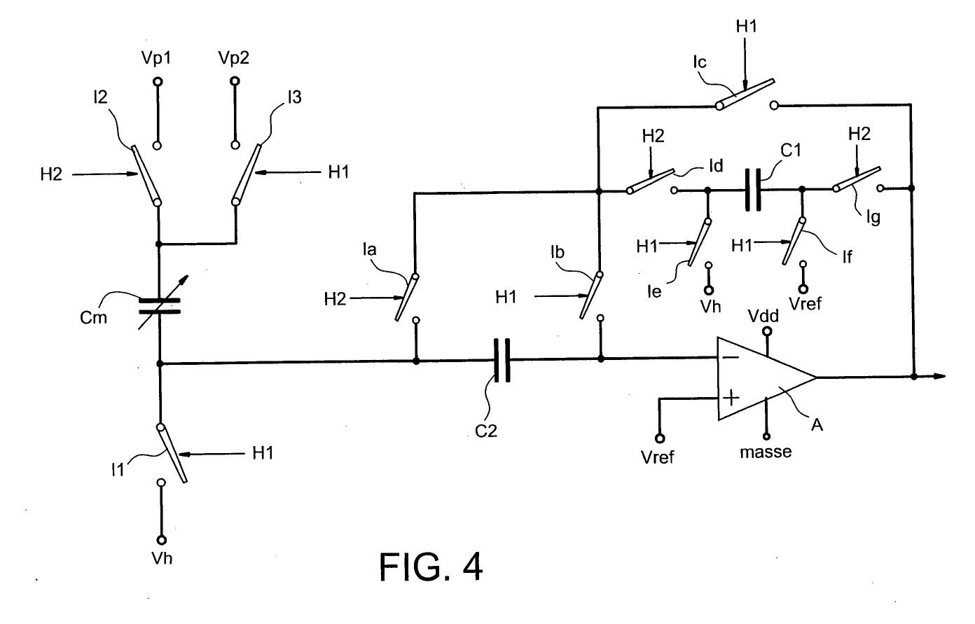

The circuit shown in FIG. 4 enables this other disadvantage to be eliminated. In addition to the components shown in FIG. 3, the circuit shown in FIG. 4 includes four additional switches Id, Ie, If, Ig. The capacitor C1 is not in this case mounted directly parallel with respect to the switch Ic, as is the case in FIG. 3. The first plate of the capacitor C1 is connected to a first terminal of the switch Id and to a first terminal of the switch Ie, while the second terminal of the switch Id is connected to the terminal common to the switches Ia and Ib, and the second terminal of the switch Ie is connected to the high voltage Vh. Moreover, the second plate of the capacitor C1 is connected to a first terminal of the switch If and to a first terminal of the switch Ig, while the second terminal of the switch If is connected to the reference voltage Vref and the second terminal of the switch Ig is connected to the output of the operational amplifier A. The switches Ie and If are controlled by the clock signal H1 and the switches Id and Ig are controlled by the clock signal H2.

When the clock signal H1 is active (switches I1, I3, Ic, Ib, Ie, If closed and switches I2, Ia, Id, Ig open), the capacitor C1 is charged between the high voltage Vh and the reference voltage Vref. The operational amplifier is in follower mode. The output voltage of the operational amplifier is therefore substantially equal to Vref.

When the clock H2 is active (switches I1, 13, Ic, Ib, Ie, If open and switches I2, Ia, Id, Ig closed), the capacitor C1 is connected between the output of the operational amplifier A and the first plate of the capacitor Cm. The first plate of the capacitor C1 is brought to the potential Vh by means of the capacitor C2, with the second plate of the capacitor C1 remaining at the potential Vref due to the precharge between the voltages Vh and Vref, implemented when the clock H1 was active (cf. above). Thus, the output of the operational amplifier A undergoes a voltage change that is due only to the charges coming from the capacitor Cm and not to the high voltage Vh.

The capacitive measuring sensor according to the invention described in FIGS. 3 to 5 includes, by way of example, a single measuring capacitor. It is clear to a person skilled in the art that the invention can also be applied to capacitive sensors including a plurality of measuring capacitors such as, for example, capacitive sensors with two capacitors having a common plate.

1. Capacitive sensor including at least one measuring capacitor (Cm) having a first plate and a second plate of which at least one plate is a mobile plate capable of moving with respect to a rest position when, in a measuring phase, a measuring voltage is applied between the first and second plates, characterised in that it includes means for applying, simultaneously to the measuring voltage, between the first and second plates, an actuation voltage (Va) capable of bringing the first and second plates to a position substantially equal to the rest position.

2. Capacitive sensor according to claim 1, characterised in that the means (I, I2, I3) for simultaneously applying, in a measuring phase, a measuring voltage and an actuation voltage (Va) include:
a first switch (I1) having a first terminal connected to the first plate of the measuring capacitor and a second terminal connected to a first voltage Vh, which first switch (I1) is controlled by a first clock signal (H1), and
a second switch (I2) having a first terminal connected to the second plate of the measuring capacitor (Cm) and a second terminal connected to a first operation voltage Vp1 so that:
Vp1=Vdd+Va
where Va is the actuation voltage and Vdd is a second voltage, which second switch (I2) is controlled by a second additional clock signal (H2) that does not overlap with the first clock signal, and
a third switch (I3) having a first terminal connected to the second plate of the measuring capacitor (Cm) and a second terminal connected to a second operation voltage Vp2 so that the second operation voltage is written:
Vp2=Vref+Va,
where Vref is a reference voltage,
which third switch (I3) is controlled by the first clock signal (H1).

3. Capacitive sensor according to claim 2, characterised in that the second plate of the measuring capacitor (Cm) is connected to the first terminal of a fourth switch (I4) of which the second terminal is connected to the inverting input (−) of an operational amplifier (A) of which the supply voltage is the voltage Vdd and of which the non-inverting input (+) is connected to the reference voltage Vref, wherein the fourth switch (I4) is controlled by the second clock signal (H2), a fifth switch (I5) and a negative feedback capacitance (C1) are mounted parallel between the inverting input (−) and the output of the operational amplifier (A), and the fifth switch (I5) is controlled by the first clock signal (H1).

4. Capacitive sensor according to claim 2, characterised in that the second plate of the measuring capacitor is connected to a first plate of an insulation capacitor (C2) of which the second plate is connected to the inverting input (−) of an operational amplifier (A), wherein a fourth switch (Ia) controlled by the second clock signal (H2) has a first terminal connected to the first plate of the insulation capacitor (C2), a fifth switch (Ib) controlled by the first clock signal (H1) has a first terminal connected to the second plate of the insulation capacitor (C2), the fourth (Ia) and fifth (Ib) switches have their second terminals connected to one another and to a first plate of a negative feedback capacitor (C1), of which the second terminal is connected to the output of the operational amplifier (A), wherein a sixth switch (Ic) controlled by the first clock signal (H1) is mounted parallel with respect to the negative feedback capacitor (C1), the operational amplifier (A) has a non-inverting input (+) connected to the reference voltage Vref of lower amplitude than the amplitude of the voltage Vh, and the second voltage vdd is the supply voltage of the operational amplifier (A).

5. Capacitive sensor according to claim 2, characterised in that the second plate of the measuring capacitor (Cm) is connected to a first plate of an insulation capacitor (C2) of which the second plate is connected to the inverting input (−) of an operational amplifier (A), wherein a fourth switch (Ia) controlled by the second clock signal (H2) has a first terminal connected to the first plate of the insulation capacitor (C2), a fifth switch (Ib) controlled by the first clock signal (H1) has a first terminal connected to the second plate of the insulation capacitor (C2) the fourth (Ia) and fifth (Ib) switches have their second terminals connected to one another, a negative feedback capacitor (C1) has a first plate connected to the second terminals of the fourth and fifth switches by means of a sixth switch (Id) controlled by the second clock signal (H2), and to the voltage Vh by means of a seventh switch (Ie) controlled by the first clock signal (H1), and a second plate connected to the reference voltage by means of an eighth switch (If) controlled by the first clock signal (H1) and to the output of an operational amplifier (A) by means of a ninth switch (Ig) controlled by the second clock signal (H2), a tenth switch (Ic) controlled by the first clock signal (H1) having a first terminal connected to the second terminals of the fourth and fifth switches and a second terminal connected to the output of the operational amplifier of which the non-inverting input (+) is connected to the reference voltage Vref, and the second voltage Vdd is the supply voltage of the operational amplifier (A).

6. Measuring method with the help of a capacitive sensor including at least one measuring capacitor (Cm) having a first plate and a second plate of which at least one plate is a mobile plate capable of moving, with respect to a rest position, when a measuring voltage is applied between the first and second plates, characterised in that it includes, simultaneously to the application of a measuring voltage between the first and second plates, the application, between said first and second plates, of an actuation voltage (Va) capable of bringing the first and second plates to a position substantially equal to the rest position.
